(19) United States
(12) Patent Application Publication
(10) Pub. No.: US 2009/0190194 A1
(43) Pub. Date: Jul. 30, 2009

(54) Color Correction Method for an Imaging System

(76) Inventors: Anna Y. Deer, Lexington, KY (US); Xuan Chao Huang, Lexington, KY (US); Brant D. Nystrom, Lexington, KY (US); Richard L. Reel, Georgetown, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 12/335,998

(22) Filed: Dec. 16, 2008

Related U.S. Application Data
(62) Division of application No. 10/678,993, filed on Oct. 3, 2003.

(51) Int. Cl. G03F 3/08

(52) U.S. Cl. 358/518

(57) ABSTRACT

A method for correcting color shift in an imaging system, including an imaging object, and a standard color conversion lookup table associated with the imaging object, includes measuring a plurality of test patches to obtain color data associated with the imaging object. A signature color data lookup table is generated, based on the color data, and is combined with the standard color conversion lookup table to generate a composite color conversion lookup table for use with the imaging object.

### CROSS REFERENCE TO RELATED APPLICATION

Pursuant to 37 C.F.R. § 1.78, this application is a divisional and claims the benefit of the earlier filing date of application Ser. No. 10/678,993 filed Oct. 3, 2003 entitled “Color Correction Method for an Imaging System.”

### BACKGROUND OF THE INVENTION

1. Field of the Invention

The present invention relates to an imaging system, and, more particularly, to a method for correcting color shift in an imaging system that occurs due to variations in printing cartridges, scanners, and/or substrates.

2. Description of the Related Art

In recent years, the use of computers for home and business purposes has increased significantly. Computer systems typically incorporate a computer monitor, a scanner, and a printer. Users frequently employ such systems for scanning, modifying, and/or creating various color documents. The documents may include personal greeting cards, photographs, pamphlets, flyers, brochures, business presentations, business cards, and other personal or business related documents. Such color documents are usually reproduced on a substrate using a personal or business printer, and distributed to various recipients, such as family or friends, or individual/business consumers. During the making or reproducing of such documents, it may be necessary to use more than one scanner or printer, or to replace the supply of substrate, e.g., paper, used for printing, or to replace a printing cartridge. It is desirable that the reproduced documents appear consistent, notwithstanding the use of more than one scanner, printer, substrate, or printing cartridge.

However, in color reproduction, a common problem that occurs is color shift due to variations in components of a color reproduction system. For example, an ink jet printer may produce different colors for the same input image when using different cartridges, due to variations in the sizes of the nozzles that eject the ink, variations in the performance of the heater chip, etc. Similarly, all-in-one (AIO) systems, which typically include a printer/scanner/copier and a fax machine, may have different color outputs due to variations in scanner output, as well as due to variations in printing cartridges. In addition, color reproduction systems may have significant color shifts between one factory-calibrated substrate and an un-calibrated substrate, or between one un-calibrated substrate and another un-calibrated substrate. For example, one substrate may absorb more ink than another, may be less reflecting than another substrate, or may have a darker background color than another substrate.

What is needed in the art is a method for correcting color shifts that occur due to variations in printing cartridges, substrates, and/or scanners.

### SUMMARY OF THE INVENTION

The present invention provides a method to correct for color shifts that occur due to variations in printing cartridges, substrates, and/or scanners.

The invention, in one form thereof, relates to a method for correcting color shift in an imaging system having an imaging object, and having a standard color conversion lookup table associated with the imaging object. The method includes the steps of measuring a plurality of test patches to obtain color data associated with the imaging object, generating a signature color data lookup table based on the color data, and combining the signature color data lookup table with the standard color conversion lookup table to generate a composite color conversion lookup table for use with the imaging object. The imaging object may be, for example, a printing cartridge, a substrate, or a scanner.

The invention, in another form thereof, relates to a method for correcting color shift in an imaging system having an imaging apparatus, and having a standard color conversion lookup table associated with the imaging apparatus. The method includes the steps of printing a plurality of test patches using a printing cartridge and the standard color conversion lookup table; measuring the plurality of test patches to obtain color data associated with the printing cartridge; generating a signature color data lookup table based on the color data; and combining the signature color data lookup table with the standard color conversion lookup table to generate a composite color conversion lookup table for use in printing with the printing cartridge.

The invention, in yet another form thereof, relates to a method for correcting color shift in an imaging system having an imaging apparatus, and having a standard color conversion lookup table associated with the imaging apparatus. The method includes the steps of printing a plurality of test patches on a substrate using the standard color conversion lookup table, measuring the plurality of test patches to obtain color data associated with the substrate, generating a signature color data lookup table based on the color data, and combining the signature color data lookup table with the standard color conversion lookup table to generate a composite color conversion lookup table for use in printing on the substrate.

The invention, in still another form thereof, relates to a method for correcting color shift in an imaging system having a scanner, and having a standard color conversion lookup table associated with the scanner. The method includes the steps of measuring a plurality of test patches to obtain color data associated with the scanner, generating a signature color data lookup table based on the color data, and combining the signature color data lookup table with the standard color conversion lookup table to generate a composite color conversion lookup table for use in scanning with the scanner.

An advantage of the present invention is the ability to render consistent color for an imaging system without regard to manufacturing variations in printing cartridges and scanners, and without regard to variations in substrates.

Another advantage is reduced memory storage requirements, by storing only a signature color data lookup table or a class code corresponding to a signature color data lookup table, rather than a complete color conversion lookup table, for performing color correction.

Yet another advantage is to reduce storage requirements and minimize color correction complexity by employing only a limited number of signature color data lookup tables as classes of color correction for use with a large number of printing cartridges, scanner, and substrates.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 is a diagrammatic depiction of an imaging system that utilizes the present invention.

FIG. 2 is a diagrammatic depiction of a colorspace converter according to the present invention.

FIG. 3 is a flowchart depicting a method according to the present invention.

FIG. 4 is diagrammatic depiction of generating a signature color data lookup table based on the present invention.

FIGS. 5A, 5B, and 5C are illustrations of certain imaging objects according to the present invention, featuring an associated identification code or category associated with each imaging object.

FIG. 6 is a flowchart depicting an embodiment of the method of FIG. 3 adapted for use in association with a printing cartridge.

FIG. 7 is a flowchart depicting another embodiment of the method of FIG. 3 adapted for use in association with a substrate.

FIG. 8 is a flowchart depicting yet another embodiment of the method of FIG. 3 adapted for use in association with a scanner.

Corresponding reference characters indicate corresponding parts throughout the several views. The exemplifications set out herein illustrate embodiments of the invention, and such exemplifications are not to be construed as limiting the scope of the invention in any manner.

### DETAILED DESCRIPTION OF THE INVENTION

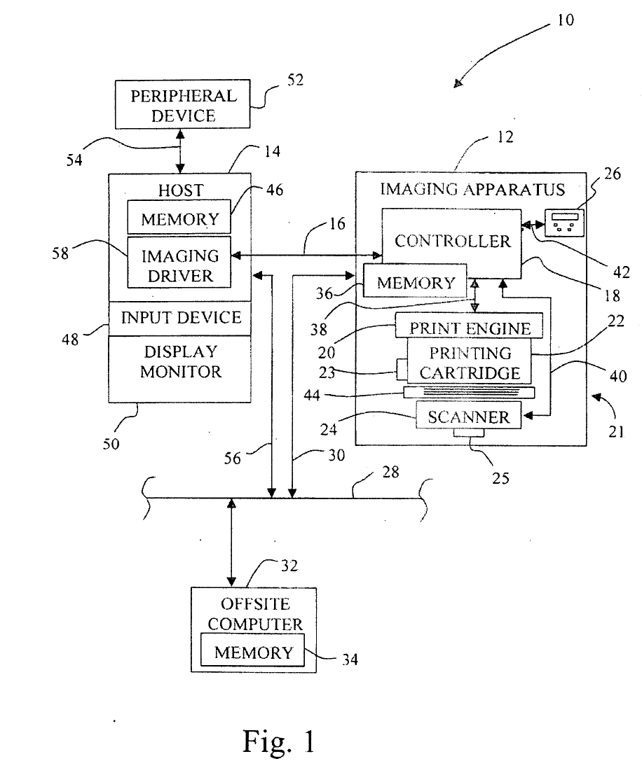

Referring now to the drawings, and particularly to FIG. 1, there is shown a diagrammatic depiction of an imaging system 10 embodying the present invention. Imaging system 10 includes an imaging apparatus 12 and a host 14. Imaging apparatus 12 communicates with host 14 via a communications link 16.

Imaging apparatus 12 can be, for example, an ink jet printer and/or copier, an electrophotographic printer and/or copier, or an all-in-one (AIO) unit that includes a printer, a scanner, and possibly a fax unit. As an AIO unit, imaging apparatus 12 includes a controller 18, a print engine 20, and one or more of an imaging object 21, such as a printing cartridge 22 having cartridge memory 23 and a scanner 24 having scanner memory 25, and a user interface 26. Imaging apparatus 12 has access to a network 28, such as the Internet, via a communication line 30, to interface with an offsite computer 32 having an offsite memory 34, in order to transmit and/or receive data for use in carrying out its imaging functions.

Controller 18 includes a processor unit and associated memory 36, and may be formed as one or more Application Specific Integrated Circuits (ASIC). Controller 18 may be a printer controller, a scanner controller, or may be a combined printer and scanner controller. Controller 18 communicates with print engine 20 via a communications link 38, with scanner 24 via a communications link 40, and with user interface 26 via a communications link 42. Controller 18 serves to process print data and to operate print engine 20 during printing.

In the context of the examples for imaging apparatus 12 given above, print engine 20 can be, for example, an ink jet print engine or a color electrophotographic print engine, configured for forming an image on a substrate 44, such as a sheet of paper, transparency or fabric. As an ink jet print engine, print engine 20 operates printing cartridge 22 to eject ink droplets onto substrate 44 in order to reproduce text or images, etc. As an electrophotographic print engine, print engine 20 causes printing cartridge 22 to deposit toner onto substrate 44, which is then fused to substrate 44 by a fuser (not shown).

Host 14 may be, for example, a personal computer, including memory 46, an input device 48, such as a keyboard, and a display monitor 50. A peripheral device 52, such as a digital camera, is coupled to host 14 via a communication link 54. Host 14 further includes a processor, input/output (I/O) interfaces, memory, such as RAM, ROM, NVRAM, and at least one mass data storage device, such as a hard drive, a CD-ROM and/or a DVD unit, and is connected to network 28 via a communication line 56.

During operation, host 14 includes in its memory a software program including program instructions that function as an imaging driver 58, e.g., printer/scanner driver software, for imaging apparatus 12. Imaging driver 58 is in communication with controller 18 of imaging apparatus 12 via communications link 16. Imaging driver 58 facilitates communication between imaging apparatus 12 and host 14, and may provide formatted print data to imaging apparatus 12, and more particularly, to print engine 20. Alternatively, however, all or a portion of imaging driver 58 may be located in controller 18 of imaging apparatus 12.

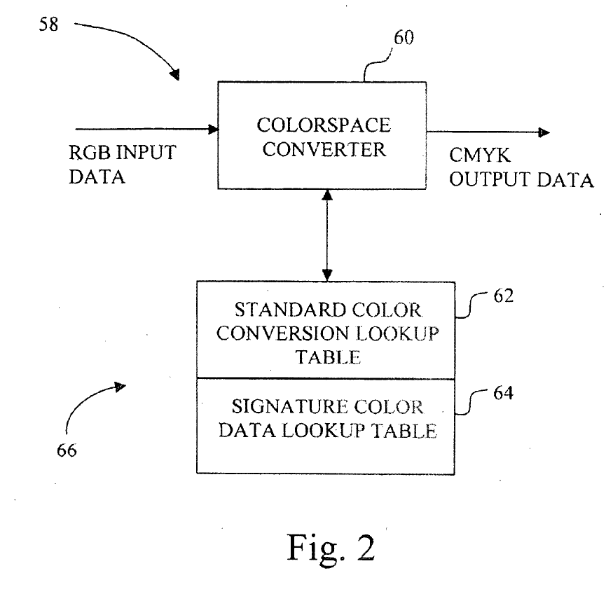

Referring now to FIG. 2, imaging driver 58 includes a colorspace converter 60. Although described herein as residing in imaging driver 58, colorspace converter 60 may be in the form of firmware or software, and may reside in either imaging driver 58 or controller 18. Alternatively, some portions of colorspace converter 60 may reside in imaging driver 58, while other portions reside in controller 18.

Coupled to colorspace converter 60 are a standard color conversion lookup table 62 and a signature color data lookup table 64, which together are used to define a composite color conversion lookup table 66. Colorspace converter 60 is used for converting color signals from a first colorspace, such as an RGB colorspace output by display monitor 50 or scanner 24, to a second colorspace, for example, CMYK (cyan, magenta, yellow, and black), which is used by print engine 20.

Standard color conversion lookup table 62 and composite color conversion lookup table 66 are multidimensional lookup tables having at least three dimensions, and include RGB values and CMYK values, wherein each CMYK output value corresponds to an RGB input value. Standard color conversion lookup table 62 and composite color conversion lookup table 66 may also include other data, such as spectral data.

Signature color data lookup table 64 is a multidimensional lookup table having at least three dimensions that includes multidimensional color data, such as CIEXYZ, CIELAB, or RGB data. For example, if imaging object 21 is a printing cartridge 22 or a substrate 44, signature color data lookup table includes CIEXYZ data or CIELAB data. If imaging object 21 is a scanner 24, signature color data lookup table 64 includes RGB data. Signature color data lookup table 64 may also include additional data, such as spectral data.

Each of standard color conversion lookup table 62, signature color data lookup table 64, and composite color conversion lookup table 66 may also be in the form of groups of polynomial functions capable of providing the same multidimensional output as if in the form of lookup tables. Standard color conversion lookup table 62 is the basic color conversion lookup table used by imaging apparatus 12, whereas signature color data lookup table 64 is specifically associated with the color shift correction of the present invention. As shown in FIG. 2, for example, colorspace converter 60 converts input RBG color data for a displayed or scanned image into color shift corrected CMYK output data, using composite color conversion lookup table 66, that may be printed by print engine 20.

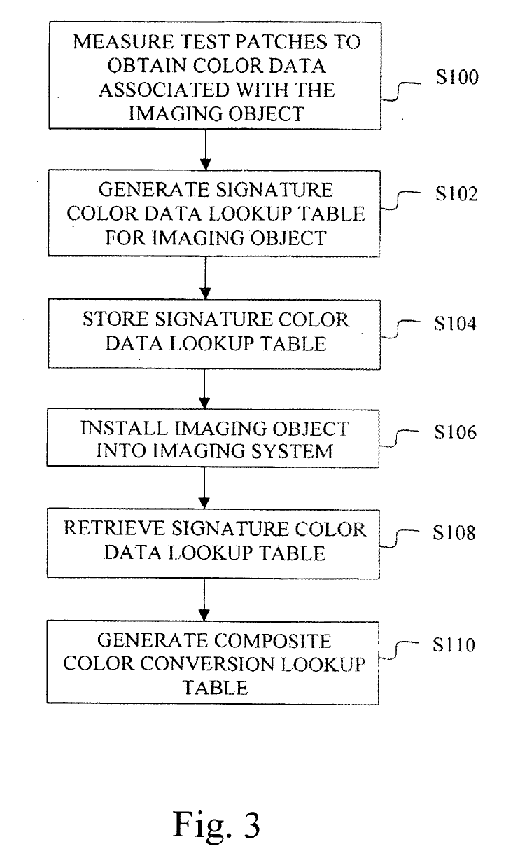

Referring now to FIG. 3, there is generally depicted a method for correcting color shift in an imaging system 10 having an imaging object 21, and having at least one standard color conversion lookup table 62 associated with imaging object 21. Here, the term “imaging object,” relates to imaging components that are used by imaging system 10 in creating, scanning, or outputting images, such as, for example, printing cartridge 22, scanner 24, or various substrates 44, as well as any other component of an imaging system that may be subject to replacement at the end of its useful life or when its supply is exhausted. The method of the present invention provides correction for color shift that occurs due to variations between any imaging objects 21 of the same type, e.g., differences between different printing cartridges 22, differences between different scanners 24, or differences between different substrates 44. Such differences may include, for example, those differences resulting from imaging object 21 manufacturing and assembly tolerances, subcomponent tolerances, the use of different manufacturers or different manufacturing lots, dye variations in substrates, substrate composition variations, variations in substrate light absorption and/or reflection characteristics, variations in imaging system 10 ambient temperature and/or humidity that may affect a substrate's performance, etc. Thus, by virtue of the present invention, different imaging objects 21 of the same type may be employed by a user, a first time or subsequent times, while providing consistent color reproduction, without regard to changing or replacing a particular imaging object 21 that has reached the end of its useful life, the end of its need for a current color reproduction job, or the supply of a consumable of which has been exhausted.

At step S100, the function of measuring a plurality of test patches 68 to obtain color data 69 associated with the imaging object 21 is performed. For example, if the imaging object 21 is a printing cartridge 22, the test patches 68 are those that were printed using the printing cartridge 22, hence the color data 69 obtained by measuring the test patches is associated with the printing cartridge 22. Color data 69 represents the printed colors on test patches 68, and may be separated into device-independent components, for example, luminance and chrominance components or L*, a* and b* components, as well as device-dependent components, such as constituent RGB (red, green blue) or CMYK (cyan, magenta, yellow, and black) components. If the imaging object 21 is print media, i.e., substrate 44, the test patches 68 are those that were printed on the particular substrate 44 having its particular characteristics, such as substrate color, ink absorption, and surface characteristics, e.g., glossy, flat, etc. If the imaging object 21 is a scanner, such as scanner 24 associated with an all-in-one imaging apparatus 12, the test patches 68 are standardized test patches provided by the manufacturer of the imaging apparatus 12 or scanner 24, for use in setting up scanner 24.

At step S102, the function of generating a signature color data lookup table 64 based on color data 69 is performed. The signature colors of an object (cartridge, scanner, substrate, etc.) are a small set of colors that can be used to characterize the object, or to classify the object into a class of objects with similar color characteristics. The signature colors are defined in terms of display monitor 50 RGB colors rather than the print engine 20 CMYK colors since the former has the minimum number of colorants used in full color reproduction; colors of other color reproduction systems, e.g., CMYK, can be mathematically reconstructed as combinations of RGB colors, no matter how many actual colorants the color reproduction system employs.

The procedure for selecting signature colors is as follows: Along each RGB primary color axis (R, G, or B), n even-spaced points over the whole range are selected. The number of all combinations of the n points will be n³. This includes the individual channel properties and their cross talks. Since the individual channel properties are very important, m additional even-spaced points between each set of two neighboring points along each primary axis are selected, for a total of m(n−1) additional points for each axis. Thus, the total number (N) of the signature colors is given by:

N=n³+3m(n−1) (Equation 1)

In a typical monitor, such as display monitor 50, over 16 million RGB colors are available. Theoretically, the more colors selected as signature colors, the more accurate the color correction will be. However, other considerations usually affect the amount of signature colors that are selected, for example, cost considerations due to measuring time, memory size, etc., and system response time or system errors due to increased computational complexity, a smaller number of signature colors is typically selected. For example, experience has shown that setting n=3, and m=1, for a total of N=33 signature colors works well for a glossy substrate 44. In other color reproduction applications, setting n=5, and m=0, for a total of N=125 signature colors has provided positive results. It may be appreciated by those skilled in the art that the number of signature colors to be selected will depend upon color correction accuracy requirements, as well as the particular applications of the imaging apparatus 12 and imaging objects 21 for which the color shift correction is desired.

Accordingly, signature color data lookup table 64 is much smaller than standard color conversion lookup table 62, allowing signature color data lookup table 64 to be stored in inexpensive, low capacity memory systems, and allowing for fast processing, as well as fast transference of color shift correction data between computer systems, e.g., via networks, as well as between computer system components, e.g., between host 14 CPU and memory.

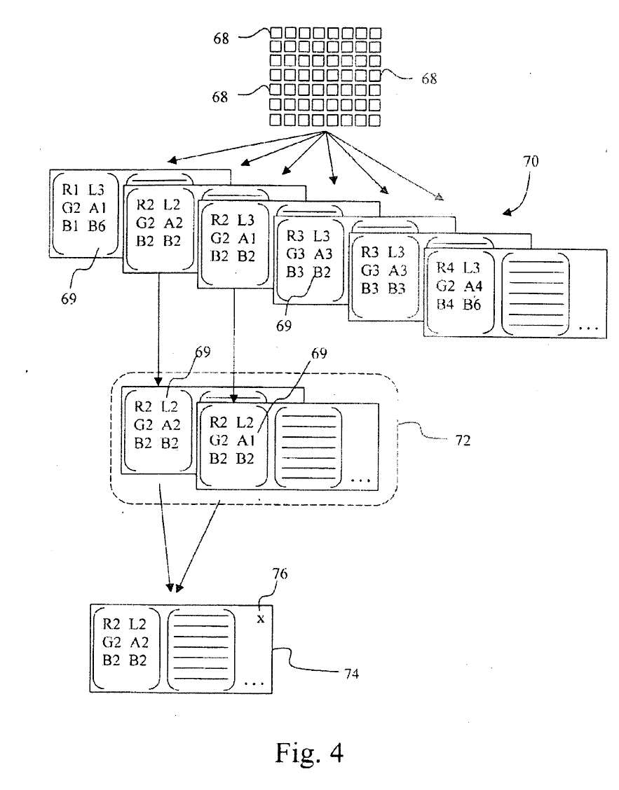

In accordance with the above discussion of step S102, a signature color data lookup table 64 has been generated for a particular imaging object 21. In some circumstances, however, it may be desirable to implement the present invention as a “class” method, in which imaging objects 21 are subdivided into classes according to their color reproduction characteristics, and a signature color data lookup table 64 is generated for each class of imaging object 21. In such a case, each imaging object 21 would belong to a class of imaging objects 21, all of which may be used in conjunction with a particular signature color data lookup table 64. Accordingly, with reference to FIG. 4 in conjunction with FIG. 3, step S102 would include generating a plurality of signature color data lookup tables 70 for a plurality of imaging objects 21, subdividing the plurality of signature color data lookup tables into classes of signature color data lookup tables 72 based on a color similarity, generating a color class table 74 for each class of signature color data lookup tables 72, assigning a class code 76 to each color class table 74, and associating the imaging object 21 with a corresponding color class table 74. The association may be made, for example, by associating class code 76 with imaging object 21. With the “class” method, the corresponding color class table 74, for example, a color table representing averaged color data 69 from the plurality of signature color data lookup tables 70 for a given class, serves as the signature color data lookup table 64 for a particular imaging object 21.

Referring back to FIG. 3, at step S104, the signature color data lookup table 64 is stored for later access by imaging system 10. Signature color data lookup table 64 is stored in a memory associated with the imaging object 21, such as cartridge memory 23, scanner memory 25, or any substrate memory that is associated with substrate 44 or affixed to or implanted into substrate 44. Here, the phrase, “memory associated with the imaging object,” refers to any type of storage method or system suitable for storing and accessing information pertaining to signature color data lookup table 64, including electrical or electronic storage or any storage based on electrical, electronic, magnetic, or electromagnetic properties, optical storage, chemical or biological based storage, mechanical storage, silicon or other storage chips, disks or other storage drives, physical impressions, etc. Alternatively, signature color data lookup table 64 is stored in a memory associated with imaging system 10, such as memory 36 of controller 18, memory 46 of host 14, as part of imaging driver 58, or stored in an offsite memory, such as offsite memory 34 of computer 32.

If the “class” method of the present invention is utilized, step S104 would include storing each color class table 74 for access by imaging system 10 in a first memory associated with imaging object 21, such as cartridge memory 23 or scanner memory 25, a memory associated with imaging system 10, such as memory 36 of controller 18, memory 46 of host 14, as part of imaging driver 58, or stored at an offsite location, such as offsite memory 34 of offsite computer 32. In addition, step S104 would include storing class code 76 in a second memory, wherein the second memory is the memory associated with imaging object 21 as set forth above, the memory associated with imaging system 10 as set forth above, or an offsite location, such as offsite memory 34.

At step S106, the imaging object 21 is installed into imaging system 10 or imaging apparatus 12. For example, if the imaging system 10 is new, a printing cartridge 22, scanner 24, or substrate 44 may be installed for the first time. On the other hand, there may be circumstances in which it may be appropriate or desirable to replace a printing cartridge 22 or scanner 24 with a different or new cartridge 22 or scanner 24, or to replace or replenish a supply of substrate 44 with a new supply of substrate 44 from a different substrate category or a different supplier of substrate 44.

At step S108, signature color data lookup table 64 is retrieved from the memory in which it was stored in step S104. If the “class” method is utilized, step S108 would include retrieving class code 76 from the memory in which it was stored, and retrieving signature color data lookup table 64 from the memory in which it was stored.

At step S110, the function of combining signature color data lookup table 64 with standard color conversion lookup table 62 is performed, to generate a composite color conversion lookup table 66 for use with imaging object 21 is performed. Thereafter, during color reproduction with imaging system 10, colorspace converter 60 of imaging driver 58 converts input RBG color data for a displayed or scanned image into color shift corrected CMYK output data, using composite color conversion lookup table 66.

The method of the present invention accommodates many different memory storage options, such as those indicated with regard to step S106, in order to provide wide latitude in implementing the present invention. For example, if the imaging object includes an associated memory, such as cartridge memory 23 or scanner memory 25, and the associated memory is of sufficient size to store signature color data lookup table 64, a signature color data lookup table 64 may be stored in each imaging object 21 for use in performing color reproduction. Signature color data lookup table 64 would automatically be retrieved by imaging system 10 or imaging apparatus 12 upon the installation of imaging object 21 for use in generating composite color conversion lookup table 66.

If a memory associated with imaging object 21 is not large enough to store signature color data lookup table 64, class code 76 may be stored in the memory associated with imaging object 21. In such a case, signature color data lookup table 64 may be stored in one of the other mentioned memories, along with the corresponding class code 76. The signature color data lookup table may then be retrieved from such memory based on the class code 76 stored in the memory associated with imaging object 21. For example, if signature color data lookup table 64 is stored in memory 36, memory 46, or as part of imaging driver 58, imaging system 10 or imaging apparatus 12 might be programmed such that upon the installation of imaging object 21, class code 76 is retrieved automatically from imaging object 21 memory, and then the signature color data lookup table 64 is automatically retrieved from memory, based on class code 76.

In another implementation, signature color data lookup table 64 is stored in offsite memory 34 of offsite computer 32. In such a case, imaging system 10 or imaging apparatus 12 is used to access offsite memory 34 via network 28, such as the Internet, and to retrieve signature color data lookup table 64 based on class code 76.

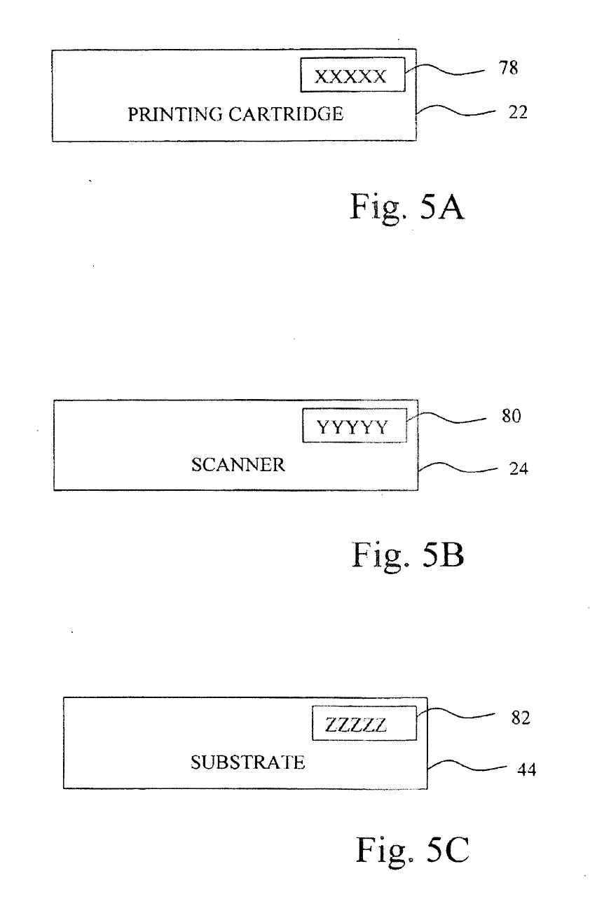

In yet another implementation, an identification code or category is associated with imaging object 21. For example, with reference to FIG. 5A, printing cartridge 22 may be provided with an identification code 78, such as a serial number, manufacturing lot, etc. Similarly, with reference to FIG. 5B, scanner 24 may be provided with an identification code 80. In addition, with reference to FIG. 5C, substrate 44 might pertain to an associated category 82, such as a type of substrate, a substrate manufacturer's version of a standard substrate, a custom substrate etc., wherein category 82 represents a catalogue number, a manufacturer code, a lot number, etc., or some form of identifier for a substrate 44; many categories 82 of substrate 44 are commercially available for business or personal printing. In such an implementation, signature color data lookup table 64 is retrieved from the memory in which it was stored based on the corresponding identification code or category. For example, a manufacturer of imaging objects 21 might keep a web site available to its customers, by which signature color data lookup table 64 might be retrieved from offsite memory 34 by entering the corresponding identification code or category associated with the imaging object 21 into a web page.

It is thus readily understood that many implementations of the present invention are possible to conveniently provide for correcting color shift that occurs due to variations in imaging objects.

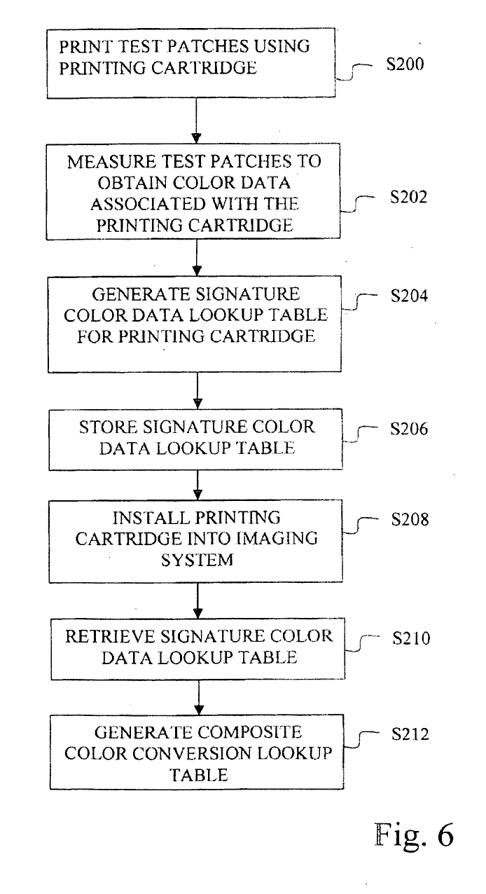

Referring now to FIG. 6, an embodiment of the present invention is depicted, in particular, a method for correcting color shift in an imaging system 10 having an imaging apparatus 12, and having at least one standard color conversion lookup table 62 associated with imaging apparatus 12.

At step S200, a plurality of test patches 68 is printed, using printing cartridge 22 and standard color conversion lookup table 62. The test patches are printed at the manufacturer, or, alternatively, by the end user of imaging apparatus 12.

At step S202, the plurality of test patches 68 is measured to obtain color data 69 associated with printing cartridge 22. The measuring is performed at the factory as part of manufacturing printing cartridge 22. Alternatively, the measuring is performed by the end user, employing imaging system 10 or imaging apparatus 12, based on scanner 24 or an appropriate sensor onboard imaging system 10 or imaging apparatus 12.

At step S204, a signature color data lookup table 64 is generated, based on color data 69.

If the “class” method of the present invention is used, in which printing cartridges 22 are subdivided into classes, a signature color data lookup table 64 is generated for each printing cartridge 22 class. Accordingly, step S204 would include generating a plurality of signature color data lookup tables 70 for a plurality of printer cartridges 22, subdividing the plurality of signature color data lookup tables 70 into classes of signature color data lookup tables 72 based on a color similarity, generating a color class table 74 for each class of signature color data lookup tables 72, assigning a class code 76 to each color class table 74, and associating printing cartridge 22 with a corresponding color class table 74. The association may be made, for example, by associating class code 76 with printing cartridge 22. With the “class” method, the corresponding color class table 74 serves as signature color data lookup table 64 for printing cartridge 22.

At step S206, signature color data lookup table 64 is stored in a cartridge memory 23 associated with printing cartridge 22. Alternatively, signature color data lookup table 64 is stored in an imaging system 10 memory, such as memory 36 of controller 18, memory 46 of host 14, as part of imaging driver 58, or stored in offsite memory 34 of computer 32, accessible by imaging system 10 via network 28.

If cartridge memory 23 is not available for storing signature color data lookup table 64, other alternatives are possible within the present invention. For example, the method includes the steps of associating an identification code 78 (reference FIG. 5A) with printing cartridge 22, and associating identification code 78 with signature color data lookup table 64. Identification code 78 may be, for example, a serial number or manufacturing lot number of printing cartridge 22, or may be any other code that is convenient for associating printing cartridge 22 with signature color data lookup table 64.

In the “class” method of the present invention, step S206 includes storing each color class table 74 in a first memory accessible by imaging system 10, and storing class code 76 in a second memory accessible by imaging system 10. For example, the first memory can be an imaging system memory, such as memory 36 of controller 18, memory 46 of host 14, or as part of imaging driver 58, and the second memory can be a cartridge memory 23 associated with printing cartridge 22.

Alternatively, for example, if cartridge memory 23 is not available for storing class code 76, class code 76 may be stored at a website maintained by the manufacturer, distributor, or retailer of printing cartridges 22, based on an identification code 78. Accordingly, the present invention includes the steps of associating identification code 78 with printing cartridge 22, and associating identification code 78 with class code 76. In such a case, the first memory is an imaging system memory, as set forth above, and the second memory is offsite memory 32 accessible by imaging system 10 via network 28. Class code 76 is then later retrieved in step S210 based on identification code 78 associated with printing cartridge 22.

At step S208, printing cartridge 22 is installed into the imaging system 10 or imaging apparatus 12.

At step S210, signature color data lookup table 64 is retrieved from cartridge memory 23. Alternatively, class code 76 is retrieved from the aforementioned second memory, for example, based on identification code 78, and signature color data lookup table 64 is then retrieved from the aforementioned first memory based on class code 76. Otherwise, signature color data lookup table 64 is retrieved from offsite memory 34, based on identification code 78.

At step S212, signature color data lookup table 64 is combined with standard color conversion lookup table 62 to generate a composite color conversion lookup table 66 for use in printing with printing cartridge 22. Composite color conversion lookup table 66 is generated with reference to color output provided by a factory-calibrated “standard cartridge,” which represents standard color conversion lookup table 62, so that printing with printing cartridge 22 and composite color conversion lookup table 66 yields a color output the same as the “standard cartridge.”

The color relationship between input RGB values and the output of the standard cartridge in CIELAB device-independent color space may be described as follows:

LAB₀=f(RGB), (Equation 2)

wherein “LAB₀” represents the CIELAB color values (L₀*a₀*b₀*) that reflect the output of the “standard cartridge” in device-independent color space coordinates, i.e., standard color conversion lookup table 62 output color values expressed in device-independent color space; “RGB” represents input color values (0-255) in RGB color space, i.e., the color space of display monitor 50 or scanner 24; and “f( )” denotes that LAB₀ is a function of the RGB input values, which may be implemented as a lookup table or a group of polynomial functions.

Similarly, the color relationship between input RGB values and the output of a given printing cartridge 22 to be corrected, expressed in device-independent CIELAB color space, may be given by:

LAB=q(RGB), (Equation 3)

wherein “LAB” represents the CIELAB color values (L*a*b*) that reflect the output of printing cartridge 22, and “q(RGB)” denotes that LAB is a function of input RGB color values.

Equations 2 and 3 are obtained through the same standard color conversion lookup table, as follows, expressed in device-dependent CMYK color space:

DCS=p(RGB), (Equation 4)

wherein “DCS” represents the digital counts (i.e., 0-255) of the printer inks (c, m, y, k) for a CMYK (cyan, magenta, yellow, and black) imaging apparatus 12, expressed as a function of the input RGB values.

Now, for a given RGB input, LAB may not be equal to LAB₀, due to variations in printing cartridge 22 relative to the “standard cartridge.” For example, variations in the sizes of ink-ejecting nozzles, or variations in heater chip output, may affect the output of printing cartridge 22. Accordingly, it is desirable to correct LAB, so that the same RGB input values when printing with printing cartridge 22 will produce the same output, LAB₀, as with the “standard cartridge.”

From Equation 3, points can be found, for example (R+dR, G+dG, B+dB), which produce LAB₀. Then, from Equation 4, new digital counts, (DCS+delta DCS), are found by using (R+dR, G+dG, B+dB), wherein “delta DCS” data is based on signature color data lookup table 64. Using the new digital counts, (DCS+delta DCS), the given RGB input will produce output LAB that equals LAB₀. The color relationship between the RGB input values and (DCS+delta DCS) represents a corrected color relationship, which is implemented as composite color conversion lookup table 66 for use with printing cartridge 22.

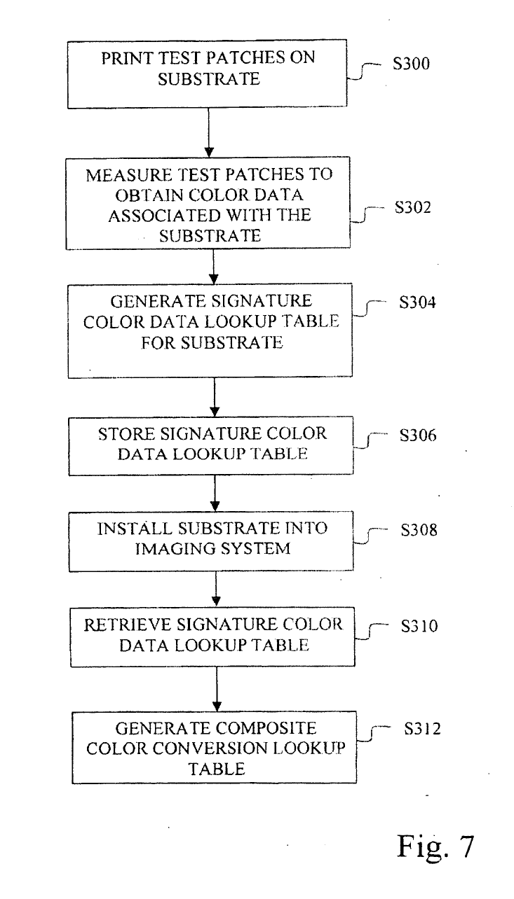

Referring now to FIG. 7, another embodiment of the present invention is depicted, in particular, a method for correcting color shift in an imaging system having an imaging apparatus 12, and having at least one standard color conversion lookup table 62 associated with imaging apparatus 12.

At step S300, a plurality of test patches 68 is printed on substrate 44 using standard color conversion lookup table 62. The test patches 68 are typically printed at the factory by the manufacturer of imaging apparatus 12 or printing cartridge 22 on a variety of categories 82 of substrate 44, yielding many test patches 68 printed on each of many categories 82 of substrate 44. Alternatively, test patches 68 may be printed by the end user with imaging apparatus 12 of imaging system 10 for the particular substrate 44 or category 82 of substrate 44 on which the user desires to print images, documents, etc.

At step S302, the plurality of test patches 68 are measured to obtain color data 69 associated with substrate 44. The measuring is typically performed at the factory by the manufacturer of imaging apparatus 12 or printing cartridge 22. Alternatively, the measuring is performed by the end user with imaging system 10 or imaging apparatus 12, based on scanner 24 or a sensor onboard imaging system 10 or imaging apparatus 12.

At step S304, signature color data lookup table 64 is generated, based on color data 69. If performed at the factory, the manufacturer typically generates a plurality of signature color data lookup tables 70 for a plurality of substrates 44, e.g., a plurality of categories 82 of substrate 44, and/or many pieces of substrate 44 having the same category 82. Signature color data lookup table 64 is then determined based on the plurality of signature color data lookup tables 70, and substrate 44 is associated with signature color data table 64. For example, signature color data lookup table 64 may be an average of a plurality of signature color data lookup tables 70 for each category 82 of substrate 44, so that a signature color data lookup table 64 is generated that corresponds to each category 82 of substrate 44.

If the “class” method of the present invention is used, a signature color data lookup table 64 is generated for each class of substrate 44. Accordingly, step S304 would include subdividing the plurality of signature color data lookup tables 70 into classes of signature color data lookup tables 72 based on a color similarity, generating a color class table 74 for each class of signature color data lookup tables 72, assigning a class code 76 to each color class table 74, and correlating each category 82 with a corresponding of each class code 76, wherein each class code 76 is associated with at least one category 82 of the plurality of categories 82. Thus, there may be more than one category 82 associated with a particular class code 76.

Step S304 also includes associating substrate 44 with a corresponding color class table 74, which serves as signature color data lookup table 64 for the particular substrate 44.

At step S306, signature color data lookup table 64 is stored in a first memory accessible by imaging system 10. The first memory may be an imaging system 10 memory, such as memory 36 of controller 18, memory 46 of host 14, or part of imaging driver 58. Alternatively, the first memory may be an offsite memory accessible by imaging system 10 via network 28, for example, offsite memory 34 of computer 32. In addition, the first memory may also be a memory associated with substrate 44.

If the “class” method of the present invention is used, step S306 includes storing each color class table 74 in the first memory, and storing class code 76 in a second memory accessible by imaging system 10.

In order to provide the maximum flexibility and convenience for the user, various combinations and permutations regarding the first memory and second memory are possible with the present invention. For example, the first memory may be an imaging system 10 memory, as described above, and the second memory also an imaging system 10 memory; or, the first memory may be an imaging system 10 memory and the second memory offsite memory 34, accessible by imaging system 10 via network 28. Conversely, the first memory may be offsite memory 34, and the second memory an imaging system 10 memory; or, the first memory may be offsite memory 34 and the second memory also offsite memory 34. In addition, the second memory may also be a memory associated with substrate 44.

At step S308, substrate 44 is installed, i.e., loaded, into the imaging system 10 or imaging apparatus 12.

At step S310, signature color data lookup table 64 is retrieved from the first memory. If the “class” method of the present invention is utilized, step S310 includes retrieving class code 76 from the second memory based on the category 82, and retrieving signature color data lookup table 64 from the first memory based on class code 76. Thus, for example, in order to retrieve signature color data lookup table 64, a user may enter the category 82 of substrate 44 into user interface 26 of imaging apparatus 12 or into imaging system 10 via input device 48 of host 14. The class code 76 is then retrieved from the second memory by imaging system 10 based on the category 82, and then, signature color data lookup table 64 is retrieved from the first memory, based on class code 76.

At step S312, signature color data lookup table 64 is combined with standard color conversion lookup table 62 to generate composite color conversion lookup table 66 for use in printing on substrate 44. Here, the procedure to correct substrate color shifts is similar to that of correcting cartridge color shifts for printing cartridge 22. Composite color conversion lookup table 66 is generated with reference to color output provided on a factory-calibrated “standard substrate” by a factory-calibrated “standard cartridge” so that later printing with substrate 44 yields a color output the same as the “standard cartridge” printing on the “standard substrate”

The color relationship between input RGB values and the output of the standard cartridge in CIELAB device-independent color space may be described as follows:

LAB₀=f(RGB) (Equation 5)

wherein “LAB₀” represents the CIELAB color values (L₀*a₀*b₀*) that reflect the output of the “standard cartridge” on the “standard substrate” in device-independent color space coordinates, i.e., standard color conversion lookup table 62 output color values expressed in device-independent color space; “RGB” represents input color values (0-255) in RGB color space, i.e., the color space of display monitor 50 or scanner 24; and “f( )” denotes that LAB₀ is a function of the RGB input values, which may be implemented as a lookup table or a group of polynomial functions.

Similarly, the color relationship between input RGB values and the output on a given substrate 44 to be corrected, expressed in device-independent CIELAB color space, may be given by:

LAB=q(RGB) (Equation 6)

wherein “LAB” represents the CIELAB color values (L*a*b*) that reflect the output on substrate 44, and “q(RGB)” denotes that LAB is a function of input RGB color values.

Equations 5 and 6 are obtained through the same standard color conversion lookup table 62, as follows, expressed in device-dependent CMYK color space:

DCS=p(RGB) (Equation 7)

wherein “DCS” represents the digital counts (i.e., 0-255) of the printer inks (c, m, y, k) for a CMYK (cyan, magenta, yellow, and black) imaging apparatus 12 expressed as a function of the input RGB values.

Now, for a given RGB input, LAB may not be equal to LAB₀, due to variations in substrate 44 relative to the factory-calibrated “standard substrate.” For example, variations in substrate 44 color, surface texture, ink-absorbing qualities, etc., may affect the output of printing on substrate 44. Accordingly, it is desirable to correct LAB, so that the same RGB input values when printing on substrate 44 will produce the same output, LAB₀, as with the “standard substrate.”

From Equation 6, points can be found, for example (R+dR, G+dG, B+dB), which produce LAB₀. Then from Equation 7, new digital counts, (DCS+delta DCS), are found, by using the (R+dR, G+dG, B+dB), wherein “delta DCS” data is based on signature color data lookup table 64. Using the new digital counts, (DCS+delta DCS), the given RGB input produces output LAB that equals LAB₀. The color relationship between the RGB input values and (DCS+delta DCS) represents a corrected color relationship, which is implemented as composite color conversion lookup table 66 for use with substrate 44.

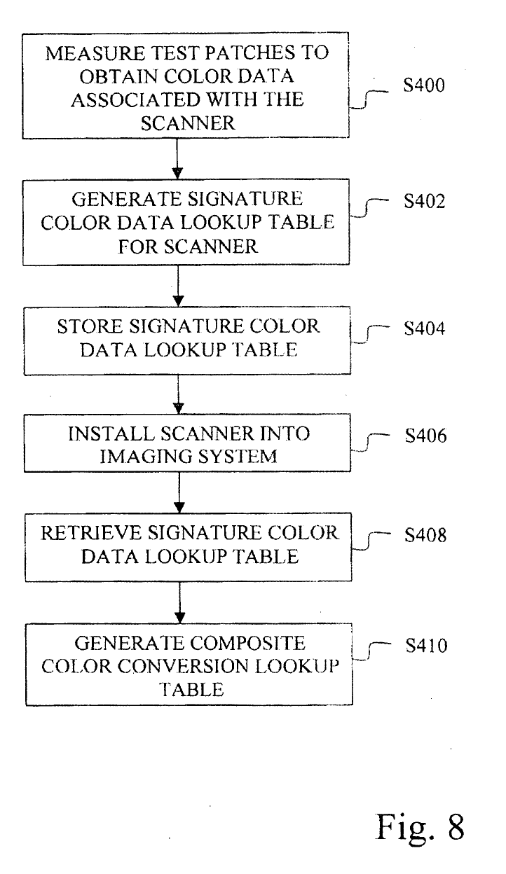

Referring now to FIG. 8, yet another embodiment of the present invention is depicted, in particular, a method for correcting color shift in an imaging system 10 having a scanner 24, and having at least one standard color conversion lookup table 62 associated with scanner 24.

At step S400, a plurality of test patches 68 is measured to obtain color data 69 associated with scanner 24. The measuring is performed at the factory as part of a manufacturing process, using scanner 24. Alternatively, the test patches 68 may be calibrated target test patches provided by the manufacturer of scanner 24, and measured by the end user with imaging system 10 or imaging apparatus 12, for example using scanner 24.

At step S402, a signature color data lookup table 64 is generated, based on color data 69.

If the “class” method of the present invention is utilized, step 402 includes generating a plurality of signature color data lookup tables 70 for a plurality of scanners 24, subdividing the plurality of signature color data lookup tables 70 into classes of signature color data lookup tables 72 based on a color similarity, generating a color class table 74 for each class of signature color data lookup tables 72, assigning a class code 76 to each color class table 74, and associating scanner 24 with a corresponding color class table 74. The association may be made, for example, by associating class code 76 with scanner 24. With the “class” method, the corresponding color class table 74 serves as the signature color data lookup table 64 for scanner 24.

At step S404, signature color data lookup table 64 is stored in scanner memory 25 associated with scanner 24. Alternatively, signature color data lookup table 64 is stored in an imaging system 10 memory, such as memory 36 of controller 18, memory 46 of host 14, as part of imaging driver 58, or stored in offsite memory 34 of computer 32, accessible by imaging system 10 via network 28.

If scanner memory 25 is not available for storing signature color data lookup table 64, other alternatives are possible within the present invention. For example, the method includes the steps of associating an identification code, such as identification code 80 (reference FIG. 5A), with scanner 24, and associating identification code 80 with signature color data lookup table 64. Identification code 80 may be, for example, a serial number or manufacturing lot number of scanner 24, or may be any other code that is convenient for associating scanner with signature color data lookup table 64.

In the “class” method of the present invention, step S404 includes storing each color class table 74 in a first memory accessible by imaging system 10, and storing class code 76 in a second memory accessible by imaging system 10. For example, the first memory can be an imaging system memory, such as memory 36 of controller 18, memory 46 of host 14, or as part of imaging driver 58, and the second memory can be a scanner memory associated with scanner 24, such as scanner memory 25.

Alternatively, for example, if scanner memory 25 is not available for storing class code 76, class code 76 is stored at a website maintained by the manufacturer, distributor, or retailer of scanner 24 based on identification code 80. Accordingly, the present invention includes the steps of associating identification code 80 with scanner 24, and associating identification code 80 with class code 76. In such a case, the first memory is an imaging system memory, as set forth above, and the second memory is offsite memory 34 accessible by imaging system 10 via network 28, wherein class code 76 is later retrieved in step S408 based on identification code 80 associated with scanner 24.

At step S406, scanner 24 is installed into the imaging system 10 or imaging apparatus 12.

At step S408, signature color data lookup table 64 is retrieved from scanner memory 25. Alternatively, class code 76 is retrieved from the aforementioned second memory, for example, based on identification code 80, and signature color data lookup table 64 is then retrieved from the aforementioned first memory based on class code 76. Otherwise signature color data lookup table 64 is retrieved from offsite memory 34, based on identification code 80.

At step S410, signature color data lookup table 64 is combined with standard color conversion lookup table 62 to generate a composite color conversion lookup table 66 for use in scanning with scanner 24. Composite color conversion lookup table 66 is generated with reference to color output provided by a factory-calibrated “standard scanner,” using a standard scan-to-file color conversion lookup table so that later scanning with scanner 24 yields a color output the same as the “standard scanner.”

In an AIO system, the cartridge variation is corrected first, using steps S200 to S212, and the corrected printing table is given by

DCS=ap(RGB₀), (Equation 8)

wherein “DCS” represents the digital counts (i.e., 0-255) of the printer inks (c, m, y, k) for a CMYK (cyan, magenta, yellow, and black) imaging apparatus 12 expressed as a function of the input RGB values, “RGB₀” represents color values (RO, Go, BO) in RGB space, and ap( ) denotes that DCS is a function of RGB₀, which may be implemented as a lookup table or a group of polynomial functions.

The input to output color relationship of the standard scan-to-file color table of the “standard scanner,” may be described as follow:

RGB₀=af(scanRGB₀) (Equation 9)

wherein “scanRGB₀” represent scanned RGB values (sR₀, sG₀, sB₀) in RGB color space, and “af( )” denotes that RGB₀ is a function of scanRGB₀, which may be implemented as a lookup table or a group of polynomial functions.

Color test patches are printed using the printing table of Equation 8 and scanned with the scanner 24 to obtain scanRGB: (sR, sG, sB). Because of variations in scanner 24 relative to the “standard scanner,” scanRGB will be different from the scanRGB₀ produced by the “standard scanner.”

Using the same color relationship “af( )” as in Equation 9, RGB may be given as follows:

RGB=af(scanRGB) (Equation 10)

Here, RGB is not the same as RGB₀, because scanRGB is not the same as scanRGB₀. The difference is “delta RGB”=RGB−RGB₀ for each signature color point, wherein “delta RGB” data is based on signature color data lookup table 64. Combining signature color data lookup table 64 with standard color conversion lookup table 62 will correct RGB to RGB₀ and produce:

RGB₀=aq(scanRGB), (Equation 11)

which represents composite color conversion lookup table 66, wherein “aq( )” is a function defining the relationship between scanRGB and RGB₀.

In yet another embodiment, in order to use an AIO system as a copier, for example, wherein a document is scanned by scanner 24, followed automatically by printing the document with printing cartridge 22, color shift correction may be obtained by using the above-described embodiment in conjunction with the embodiment set forth in steps S200 to S212. Accordingly, combining Equations 8 & 11 provides a copy color table as combined color conversion lookup table 66 for use with scanner 24 in conjunction with printing cartridge 22, as follows:

DCS=ap(aq(scanRGB))=ac(scanRGB), (Equation 12)

wherein “ac( )” denotes that the printer ink digital count DCS is a function of the scanner scanRGB.

While this invention has been described with respect to several embodiments, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1-7. (canceled)

8. A method for correcting color shift in an imaging system having an imaging apparatus, and having a standard color conversion lookup table associated with said imaging apparatus, comprising the steps of:
printing a plurality of test patches using a printing cartridge and said standard color conversion lookup table;
measuring said plurality of test patches to obtain color data associated with said printing cartridge;
generating a signature color data lookup table based on said color data; and
combining said signature color data lookup table with said standard color conversion lookup table to generate a composite color conversion lookup table for use in printing with said printing cartridge.

9. The method of claim 8, further comprising the steps of:
storing said signature color data lookup table in a cartridge memory associated with said printing cartridge;
installing said printing cartridge into said imaging apparatus; and
retrieving said signature color data lookup table from said cartridge memory.

10. The method of claim 8, wherein said generating step includes:
generating a plurality of signature color data lookup tables for a plurality of printing cartridges;
subdividing said plurality of signature color data lookup tables into classes of signature color data lookup tables based on a color similarity;
generating a color class table for each class of signature color data lookup tables;
assigning a class code to each said color class table;
storing each said color class table in a first memory accessible by said imaging system; and
storing said class code in a second memory accessible by said imaging system.

11. The method of claim 10, further including the step of associating said printing cartridge with a corresponding color class table, said corresponding color class table serving as said signature color data lookup table.

12. The method of claim 11, wherein said associating step includes associating said class code with said printing cartridge.

13. The method of claim 11, further comprising the steps of:
installing said printing cartridge into said imaging system;
retrieving said class code from said second memory; and
retrieving said signature color data lookup table from said first memory based on said class code.

14. The method of claim 13, wherein said first memory is an imaging system memory and said second memory is a cartridge memory associated with said printing cartridge.

15. The method of claim 13, wherein said first memory is an imaging system memory and said second memory is an offsite memory accessible by said imaging system via a network, said class code being retrieved based on an identification code associated with said printing cartridge.

16. The method of claim 13, wherein:
said step of associating said printing cartridge with a corresponding color class table includes associating an identification code with said printing cartridge, and associating said identification code with said class code, and
wherein said step of retrieving said class code from said second memory is based on said identification code.

17. The method of claim 8, further comprising the steps of:
storing said signature color data lookup table in an offsite memory accessible by said imaging system via a network;
installing said printing cartridge into said imaging system; and
retrieving said signature color data lookup table from said offsite memory.

18. The method of claim 17, further comprising the steps of:
associating an identification code with said printing cartridge; and
associating said identification code with said signature color data lookup table,
wherein said step of retrieving said signature color data lookup table from said offsite memory is based on said identification code.

19. The method of claim 8, wherein said measuring step is performed using said imaging system.

20-45. (canceled)
